(19) United States
(12) Patent Application Publication
(10) Pub. No.: US 2026/0161095 A1
(43) Pub. Date: Jun. 11, 2026

(54) DEVICES, SYSTEMS, AND METHODS FOR HIGH RESOLUTION PHOTOLITHOGRAPHY

(71) Applicant: TERA-PRINT LLC, Skokie, IL (US)

(72) Inventors: William O. HUTSON, Evanston, IL (US); Jeremy T. LUTZ, Chicago, IL (US); Kyle B. JUSTUS, Chicago, IL (US); Cody J. SMITH, Chicago, IL (US)

(21) Appl. No.: 19/410,428

(22) Filed: Dec. 5, 2025

Related U.S. Application Data
(60) Provisional application No. 63/728,664, filed on Dec. 5, 2024.

(51) Int. Cl. G03F 7/00

(52) U.S. Cl. CPC G03F 7/70258; G03F 7/70316; G03F 7/70725; G03F 7/70775

(57) ABSTRACT

Devices, systems, and method for high resolution photolithography can include a mounting stage for receiving a substrate in position to receive projected light for photolithography, a light processing system for projecting light onto the mounting stage for photolithography on the substrate, and a positioning system for adjusting relative positioning between the light processing system and the mounting stage. A control system for conducting operations for high resolution photolithography, can be configured to determine relative positioning between the light processing system and the mounting stage and for governing operation of the positioning system for adjusting relative positioning.

### CROSS-REFERENCE

This utility application claims the benefit of priority to U.S. Provisional Application No. 63/728,664, filed on Dec. 5, 2024, entitled “HIGH RESOLUTION PHOTOLITHOGRAPHY” the contents of which are hereby incorporated by reference in their entirety.

### FIELD

The present disclosure concerns devices, systems, and methods for photolithography. More specifically, the present disclosure concerns devices, systems, and methods for high resolution photolithography.

### SUMMARY

The present application discloses one or more of the features recited in the appended claims and/or the following features which, alone or in any combination, may comprise patentable subject matter.

According to an aspect within the present disclosure, a high-resolution photolithography system may include a mounting stage configured to presenting a target sample in position to receive high-resolution, patterned illumination for light-driven photochemistry, a light-processing system configured to provide high-resolution patterned illumination to the target sample, a positioning system configured for adjusting relative positioning between the light-processing system and the mounting stage, and a reagent system configured for application of one or more reagent materials within a patterning environment of the target sample on the mounting stage to facilitate photochemistry directed to the target sample. The high-resolution photolithography system may include a control system for governing control of the reagent system for application of one or more reagent materials within the patterning environment of the target sample. The control system may be configured for governing control of at least one of the positioning system and the light-processing system for coordinated control to facilitate high-resolution, patterned photochemistry. In some embodiments, the control system may be configured for governing control of one or more of the positioning system, the light-processing system, and the reagent system for organic material synthesis. In some embodiments, the organic material may include one or more oligomer. The organic material may include one or more organic polymer. The organic material may include one or more nucleic acid. The organic material may include one or more peptide.

In some embodiments, the light-processing system may be configured to integrate a beam pen lithography tip array to address the target sample. The beam pen lithography tip array may include at least one tip coated with a layer, the layer defining one or more small apertures for passing light. The layer may be formed as a thin metallic layer. The one or more small apertures for passing light may be formed by physical and/or chemical application. The one or more small apertures may be defined near an apex of the at least one tip. In some embodiments, the one or more apertures may be defined such that light passed therethrough for effecting photochemistry on the target sample is configured for generating nanoscale features with dimensions below the diffraction limit of the light source.

In some embodiments, the reagent system may be configured to provide liquid phase reagent material. In some embodiments, the reagent system may be configured to provide gaseous phase reagent material. The reagent system may be configured to provide reagent material in coordination with translation by the positioning system and/or spatially-patterned projected light by the light-processing system for light-directed patterning on the target sample. In some embodiments, translation by the positioning system may include XY translation. Translation by the positioning system may include XYZ translation. Spatially patterned projected light may include spatially patterned projected light for light-directed 3D patterning. Spatially patterned projected light may include spatially patterned projected light for light-directed 2D patterning. In some embodiments, spatially patterned projected light may include spatially patterned projected light for light-directed multiplexed patterning. Spatially patterned projected light may include spatially patterned projected light for light-directed multiplexed 2D patterning and/or multiplexed 3D patterning.

In some embodiments, the reagent system may be configured for concurrent application of a first reagent material that is photo-responsive to a first light wavelength and a second reagent material that is photo-responsive to a second light wavelength. The first and second light wavelengths may be different from each other for in-registry and/or hybrid high-resolution patterning. The reagent system may be configured for application of reagent materials as building materials for photochemical layer-by-layer synthesis of organic material into spatially encoded, high resolution arrays. In some embodiments, the organic material may include one or more oligomer. The organic material may include one or more organic polymer. The organic material may include one or more nucleic acid. The organic material may include one or more peptide.

In some embodiments, the light projection system may be configured to operate in a grayscale mode to control light dose delivered to each pixel. The reagent system may include a flow cell configured to encompass the target sample to apply reagent materials to the target sample during at least one of prior to, during, and after photolithography. In some embodiments, the light-processing system may include at least one of a spatial light modulator and a digital micromirror. The light-processing system may include projection optics. The positioning system may be configured to provide relative translational and rotational positioning adjustment between the light-processing system and the mounting stage.

In some embodiments, the light-processing system may include a tip array applied to focus light below diffraction limit. The tip array may also be configured for one or more of delivery of chemistries, mechanical stimuli, thermal triggers, and electromagnetic triggers to the target sample and/or a substrate thereof.

In some embodiments, the control system may be configured for governing operations of the reagent (fluidics) system to provide fluidics to the substrate to generate a layer of organic material on the substrate. The control system may be configured for governing operations of the light processing system to project light onto the substrate via the tip array to deprotect designated areas of the layer of organic material. The control system may be configured for governing operations of the fluidics system to provide fluidics to the substrate to generate another layer of organic material to the deprotected designated areas. The layer of organic material may include one or more nucleic acids. The other layer of organic material may include one or more nucleic acids such that the layer and the other layer comprise portions of a DNA oligomer or an RNA oligomer.

According to an aspect within the present disclosure, a (integrated) high-resolution photolithography system may include a mounting stage configured to presenting a target sample in position to receive high-resolution, patterned illumination for light-driven photochemistry, a light-processing system configured to provide high-resolution patterned illumination to the target sample, the light-processing system being integrated with a beam pen lithography tip array to address the target sample, a positioning system configured for adjusting relative positioning between the light-processing system and the mounting stage, and a reagent system configured for application of one or more reagent materials within a patterning environment of the target sample on the mounting stage to facilitate photochemistry directed to the target sample. In some embodiments, the beam pen lithography tip array may include at least one tip coated with a layer, the layer defining one or more small apertures for passing light. The layer may be formed as a thin metallic layer. The one or more small apertures for passing light may be formed by physical and/or chemical application. The one or more small apertures may be defined near an apex of the at least one tip. In some embodiments, the one or more apertures may be defined such that light passed therethrough for effecting photochemistry on the target sample is configured for generating nanoscale features with dimensions below the diffraction limit of the light source.

In some embodiment, the high-resolution photolithography system may include a control system for governing control of the reagent system for application of one or more reagent materials within the patterning environment of the target sample. The control system may be configured for governing control of at least one of the positioning system and the light-processing system for coordinated control to facilitate high-resolution, patterned photochemistry. In some embodiments, the control system may be configured for governing control of one or more of the positioning system, the light-processing system, and the reagent system for organic material synthesis. In some embodiments, the organic material may include one or more oligomer. The organic material may include one or more organic polymer. The organic material may include one or more nucleic acid. The organic material may include one or more peptide.

In some embodiments, the reagent system may be configured to provide liquid phase reagent material. In some embodiments, the reagent system may be configured to provide gaseous phase reagent material. The reagent system may be configured to provide reagent material in coordination with translation by the positioning system and/or spatially-patterned projected light by the light-processing system for light-directed patterning on the target sample. In some embodiments, translation by the positioning system may include XY translation. Translation by the positioning system may include XYZ translation. Spatially patterned projected light may include spatially patterned projected light for light-directed 3D patterning. Spatially patterned projected light may include spatially patterned projected light for light-directed 2D patterning. In some embodiments, spatially patterned projected light may include spatially patterned projected light for light-directed multiplexed patterning. Spatially patterned projected light may include spatially patterned projected light for light-directed multiplexed 2D patterning and/or multiplexed 3D patterning.

In some embodiments, the reagent system may be configured for concurrent application of a first reagent material that is photo-responsive to a first light wavelength and a second reagent material that is photo-responsive to a second light wavelength. The first and second light wavelengths may be different from each other for in-registry and/or hybrid high-resolution patterning. The reagent system may be configured for application of reagent materials as building materials for photochemical layer-by-layer synthesis of organic material into spatially encoded, high resolution arrays. In some embodiments, the organic material may include one or more oligomer. The organic material may include one or more organic polymer. The organic material may include one or more nucleic acid. The organic material may include one or more peptide.

In some embodiments, the light projection system may be configured to operate in a grayscale mode to control light dose delivered to each pixel. The reagent system may include a flow cell configured to encompass the target sample to apply reagent materials to the target sample during at least one of prior to, during, and after photolithography. In some embodiments, the light-processing system may include at least one of a spatial light modulator and a digital micromirror. The light-processing system may include projection optics. The positioning system may be configured to provide relative translational and rotational positioning adjustment between the light-processing system and the mounting stage.

In some embodiments, the light-processing system may include a tip array applied to focus light below diffraction limit. The tip array may also be configured for one or more of delivery of chemistries, mechanical stimuli, thermal triggers, and electromagnetic triggers to the target sample and/or a substrate thereof.

In some embodiments, the control system may be configured for governing operations of the reagent (fluidics) system to provide fluidics to the substrate to generate a layer of organic material on the substrate. The control system may be configured for governing operations of the light processing system to project light onto the substrate via the tip array to deprotect designated areas of the layer of organic material. The control system may be configured for governing operations of the fluidics system to provide fluidics to the substrate to generate another layer of organic material to the deprotected designated areas. The layer of organic material may include one or more nucleic acids. The other layer of organic material may include one or more nucleic acids such that the layer and the other layer comprise portions of a DNA oligomer or an RNA oligomer.

Accordingly to another aspect of the present disclosure, a high resolution photolithography system may include a mounting stage for receiving a substrate in position to receive projected light for photolithography, a light processing system for projecting light onto the mounting stage for photolithography on the substrate, a positioning system for adjusting relative positioning between the light processing system and the mounting stage; and a control system for conducting operations. These operations may include DNA and/or RNA and/or other polymer synthesis using high resolution photolithography. In some embodiments, the control system may be configured to determine relative positioning between the light processing system and the mounting stage. The control system may be configured for governing operation of the positioning system for adjusting relative positioning.

According to another aspect of the present disclosure, a method of high resolution photolithography may include defining one or more images for printing micro-and/or nano-arrays of organic materials via a light processing system mediated by massively parallel tip arrays onto at least one sample substrate, and aligning the light processing system with the at least one sample substrate received on a mounting stage. The aligning may include determining, via a control system, relative positioning between the light processing system and the tip-array. Aligning may include subsequent alignment between the light processing system/tip-array with the sample substrate mounting stage. Aligning may include governing operation of the positioning system for adjusting relative positioning. In some embodiments, the method may further include delivering the one or more digital images onto the substrate from the light processing system for priming. The organic materials may be DNA, RNA, Peptides, other Polymers, etc. Delivering the one or more digital images onto the substrate from the light processing system for priming may be to prime the substrate to receive the DNA/RNA/Peptide/Polymer bases to grow long-chain oligos.

According to another aspect of the present disclosure, a high resolution photolithography system may comprise a mounting stage for receiving a substrate in position to receive projected light for photolithography; a light processing system for projecting light onto the mounting stage for photolithography on the substrate; a positioning system for adjusting relative positioning between the light processing system and the mounting stage; and a control system for conducting operations for high resolution photolithography. The control system may be configured to determine relative positioning between the light processing system and the mounting stage and for governing operation of the positioning system for adjusting relative positioning.

In some embodiments, the light processing system may include at least one digital light projector (DLP) comprising a Digital Micromirror Device (DMD) chipset comprising a plurality of micromirrors. The control system may be configured to calibrate the DLP for illumination intensity by defining a correction profile corresponding to a duty cycle for each of the plurality of micromirrors. The control system may be configured to define the correction profile by setting the duty cycle at 100% for one of the micromirrors having the lowest native intensity as a reference micromirror. The control system may be configured for determining the duty cycle for other ones of the micromirrors by comparison to the reference micromirror.

In some embodiments, the control system may be configured to support illumination uniformity of within about ±5% of average illumination over at least 95% of an illumination area of the DLP. The control system may encode the determined duty cycle for each of micromirrors directly onto the DMD chipset. The control system may be configured to define a plurality of grayscale images from a native image. The control system may be configured to govern projection of the grayscale images in series from the light processing system onto the mounting stage to build up image-by-image printing of the native image on the substrate.

In some embodiments, the control system may be configured for conducting autofocusing by governing projection of a predetermined pattern from the light processing system onto the mounting stage for projection on the substrate, capturing an image of the pattern on the substrate having projection thereon, and decomposing the captured image of the pattern into spatial-frequency amplitude. The control system may be configured to govern adjustment of a focal plane of the DLP based on the spatial-frequency amplitude of the captured image. Configuration to govern adjustment of the focal plane may include configuration to govern at least one of adjusting a Z-position of the light projection system relative to the mounting stage, coordinating camera exposure of the substrate by time of light propagation, and maximizing contrast at edges of the predetermined pattern.

In some embodiments, the control system may be configured for conducting tip-tilt adjustment including governing the positioning system for the light processing system relative to the mounting stage to address at least two different portions of the substrate and to adjust a Z-position of the light projection system relative to the mounting stage for each of the at least two different portions of the substrate for autofocusing. The at least two different portions may include at least two different perimeter portions of the substrate. Conducting tilt-tilt adjustment may include governing the positioning system for tip-tilt including rotation of the mounting stage about at least one of X, Y, and Z axes.

In some embodiments, the high resolution photolithography system may further comprise a sample environmental control feedback system for precisely modulating the temperature and humidity of the environment for patterning the substrate. In some embodiments, the system may further comprise a sample environment control system for introduction of one or more fluids for patterning the substrate. The sample environment control system may include a sealed chamber received by the mounting stage for receiving the substrate and a fluidics system for selective introduction of the one or more fluids into the sealed chamber for patterning the substrate.

In some embodiments, the fluidics system may include a number of fluid reservoirs and a fluidic flow control system for controlling injection of the one or more fluids into the sealed chamber. The fluidic control system may include one or more fluidic chip modules for processing fluids before injection into the sealed chamber. The control system may be configured to govern operation of the one or more fluidic chip modules for multi-step printing. At least one of the one or more fluidic chip modules may be a microfluidic chip module. In some embodiments, the fluidics system may include a mixing chamber for mixing two of more fluids according to governing by the control system.

According to another aspect of the present disclosure, a method of high resolution photolithography may include defining one or more images for printing via a light processing system onto at least one sample substrate; aligning the light processing system with the at least one sample substrate received on a mounting stage, wherein aligning includes determining, via a control system, relative positioning between the light processing system and the mounting stage and governing operation of the positioning system for adjusting relative positioning; and printing the one or more images by projecting light onto the substrate from the light processing system.

In some embodiments, aligning may include autofocusing. Autofocusing may be by projection of a predetermined pattern from the light processing system onto the mounting stage for projection on the sample substrate, capture of an image of the pattern on the substrate having projection thereon, decomposition the captured image of the pattern into spatial-frequency amplitude, and adjustment of a focal plane of a DLP of the light processing system, via the control system, based on the spatial-frequency amplitude of the captured image.

In some embodiments, aligning may include tip-tilt adjustment. Tip-tilt adjustment may comprise addressing at least two different portions of the sample substrate and adjusting a Z-position of the light projection system relative to the mounting stage with respect to each of the at least two different portions of the substrate for autofocusing. The at least two different portions include at least two different perimeter portions of the substrate.

In some embodiments, printing may include injecting one or more fluids into a sealed chamber of the mounting stage, via a fluidics system. Printing may include printing high-resolution, wide-area, high-fidelity DNA microarrays onto arbitrarily sized glass substrates, via injection of fluids into the sealed fluidic chamber in coordination with DLP projection. Printing may be conducted subsequent to tip-tilt adjustment and auto-focusing.

In some embodiments, printing may include microfabricating microfluidics devices, other fluidics devices, sensors, wearable electronic devices, microelectronics, microlenses, metamaterials, microrobotics, microarray fabrication via photopatterning and/or in-situ photosynthesis, and/or tissue engineering. In some embodiments, compatible materials include but are not limited to commercial photoresists, hydrogels, biomolecules, polymers, and/or any other suitable photoresponsive materials.

According to another aspect within the present disclosure, a method of operating a high resolution photolithography system may include providing fluidics to a sample area to generate a layer of organic material, projecting light onto the sample area via a tip array to deprotect designated areas of the layer of organic material, and providing fluidics to the sample area to generate another layer of organic material to the deprotected designated area of the layer of organic material. In some embodiments, the layer of organic material may include one or more nucleic acids. The other layer of organic material may include include one or more nucleic acids such that the layer and the other layer comprise portions of a DNA oligomer or an RNA oligomer.

In some embodiments, the method may include controlling relative positioning between a light processing system and a mounting stage to orient the sample area for photochemistry. Controlling relative positioning may include calibrating a positioning system.

Additional features, which alone or in combination with any other feature(s), including those listed above and those listed in the claims, may comprise patentable subject matter and will become apparent to those skilled in the art upon consideration of the following detailed description of illustrative embodiments exemplifying the best mode of carrying out the invention as presently perceived.

### BRIEF DESCRIPTION

The detailed description may refer to the accompanying figures in which:

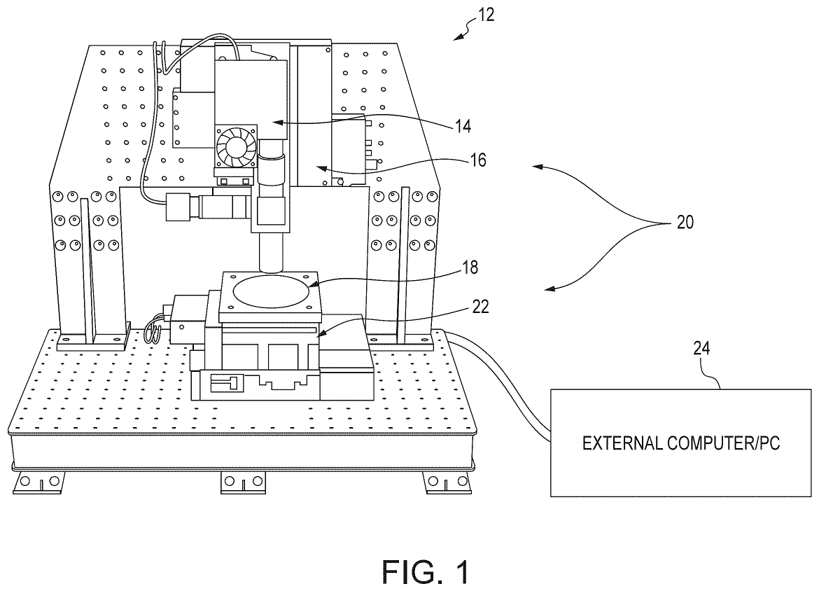

FIG. 1 (Schematic 1) is a perspective view of a high resolution photolithography system;

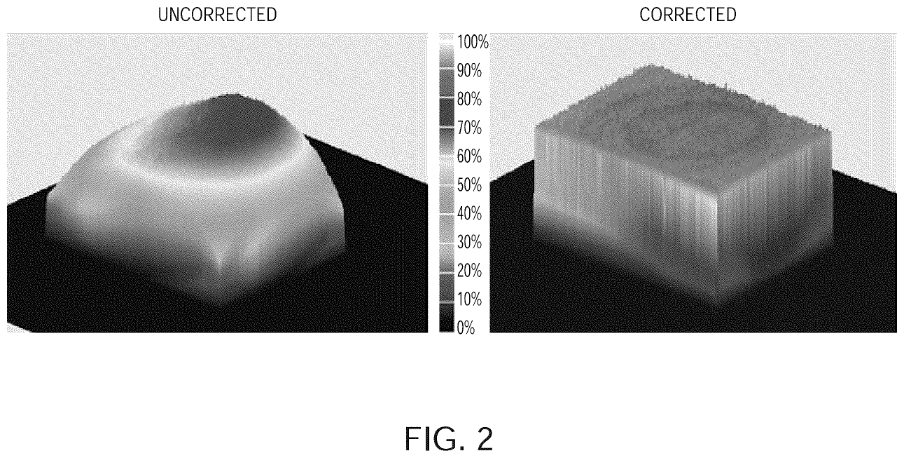

FIG. 2 (Schematic 2) is a chart representing light intensity profile of the high resolution photolithography system of FIG. 1 showing an uncorrected profile (left) and corrected profile (right);

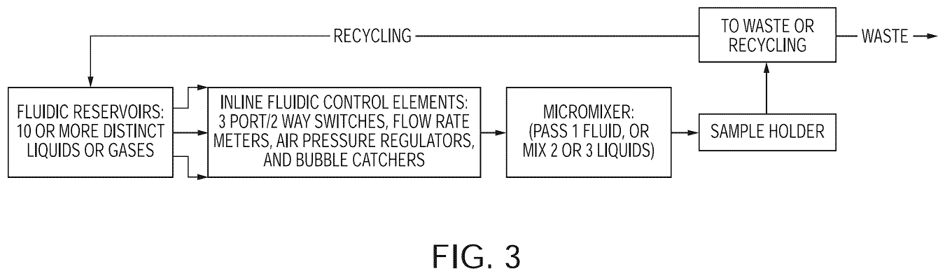

FIG. 3 (Schematic 3) is flow diagram concerning fluidics of the high resolution photolithography system of FIGS. 1 & 2;

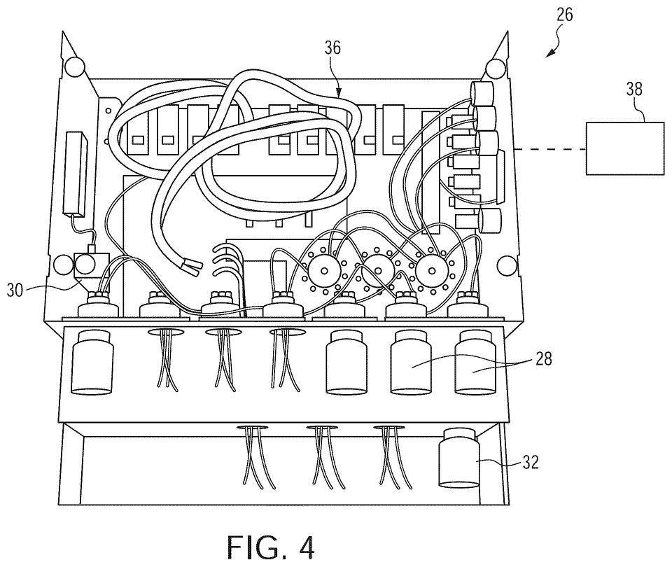

FIG. 4 is an elevation view of a fluidics system for providing precision control of fluids introduced to a sample/substrate of interest addressed by the high resolution photolithography system of FIG. 1; and

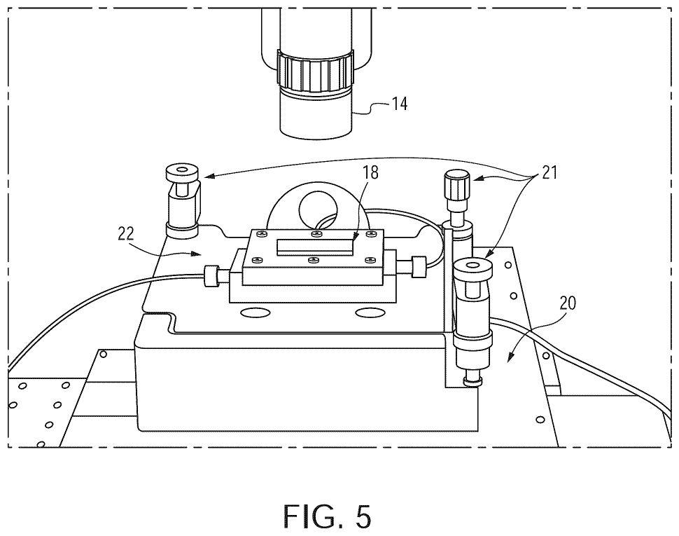

FIG. 5 is a close perspective view of a mounting stage of the high resolution photolithography system of FIG. 1.

### DETAILED DESCRIPTION

For the purposes of promoting an understanding of the principles of the disclosure, reference will now be made to a number of illustrative embodiments illustrated in the drawings and specific language will be used to describe the same.

Within the present disclosure, a maskless array-mediated photolithography devices, systems, and methods can enable the patterning of photoresponsive materials on a variety of surfaces over large areas, with high resolution. Suitable examples may include TERA-Fab DNA E as marketed by Tera-Print LLC of Skokie, IL. In the illustrative embodiment, devices, systems, and methods can include a digital light processing unit (DLP) (e.g., UV-projector) mounted to a Z-motorized stage for light focusing. A sample chamber oriented below the DLP that can be mounted with a substrate. The substrate can be mounted under sealed liquid flow. High-resolution XY (and/or Z) stages can be applied for addressing the sample area. A tip/tilt stage can be integrated into the sample stage assembly to ensure parallelism between the sample and projected light. A rotation stage can assist in ensuring that samples are loaded orthogonally relative to the light projection and for in-registry printing. Custom developed software can be implemented for operating the entire system via computer. (See Schematic 1). Additional context for appreciating innovations within the present disclosure can be understood from the following discussions.

In some embodiments, the system may constitute a modular and/or re-configurable desktop Digital Light Processor (DLP)-based photolithography and/or microscopy system with multifunctional capabilities. The system can include a core set of motion hardware including a set of translation stages capable of lateral motion in coordination with a DLP system. The DLP itself can be formed as a modular system in which a multitude of different imaging and/or patterning modalities may be performed. These modules and hot-swappable components may include but are not limited to: LED illumination module, laser illumination module, direct laser writing module, confocal camera module, objective lens/objective lens turret module.

In some embodiments, two complementary system modules may include one in which super-resolution patterning and/or imaging may be achieved through the use of a pen-tip array (BPL, PPL, AFM, TERS, plasmonic BPL) and another which provides a fluidic or reagent system. The fluidic system may allow which user-defined photochemistries (reagents) to be injected into a flow cell which controls the sample environment. The sample may be patterned via the DLP system in a configuration with or without the pen-tip array module present.

A super-resolution module can provide precision six-axis motion hardware through which rapid alignment between the pen-array and the DLP system and substrate may take place. This alignment procedure may be performed through either optical, multi or single point contact force, and/or electrical (contact, capacitive or inductive) feedback in coordination with precision Z-tip-tilt actuation of the substrate or pen-array. The entire surface can then be contacted in a parallel fashion wherein each pen tip may perform selective patterning or imaging at micro or nanoscale points via the photo-activated pen-tips illuminated by the DLP system. The pen-array is then brought out of contact with the substrate, laterally displaced and then contacted with the substrate to repeat the selective imaging or patterning step at a different position. This process can be used to scan each pen-tip over sub-regions which when stitched together, comprise the full patterning or imaging area.

The fluidic system can be formed as a modular and/or reconfigurable unit to handle various chemistries depending on the application. Fundamentally, the fluidic system can be driven by computer-controlled pneumatics, peristaltic pumps, and/or syringe pumps from which an array of fluids contained in a set of reservoirs may be selectively driven into a flow cell (either configured for the super-resolution pen array module or DLP patterning). In some configurations, automated mixing may be performed to flow a mixture of fluids via a microfluidic chip component combined with fluidic flow rate monitors in coordination with a PID control loop to drive the mixing of fluids with a user-defined composition. Fluidic hardware maintains low internal volume and tubing length is minimized to maximize the performance of the system. Various fluidic modules and devices may be integrated to perform automated pre-processing of the injected chemicals including but not limited to: heaters, degassers, filters and other various functional microfluidic chips. The fluidic system may also be configured to enable the chaining of multiple instruments operating in parallel wherein the chemical products or used reagents expelled from one instrument may be then directly injected into another to system's flow cell to repeat or build off from the relevant photochemical step on a different system. It is also may be possible to configure the fluidics such that the products of certain photolithography steps may be recycled back into the same system for subsequent chemical or photochemical processes.

Through different structural modifications and scalable nanofabrication techniques, the pen-tip arrays may be capable of performing distinct functions. These nanofabrication techniques include, but are not limited to: hot-embossing, UV-nanoimprint lithography, PDMS or PMMA micro/nano molding, template stripping, etc. These functions include the ability to perform beam pen lithography wherein a selectively illuminated pen-array coated with a light-blocking film, (e.g. gold, aluminum, etc.) and a nanoaperture at the tip apex is used to perform nanoscale photolithography beyond the diffraction limit. A pen tip-array may also be used to harness plasmonic effects by incorporating a thin (<100 nm) plasmonic metal layer (gold, silver, aluminum, etc.). Each pen may photo-selectively generate plasmon waves along the outer surface of the pen via internal illumination supplied by the DLP system. These surface plasmon waves can generate hot-electron dynamics at the apex of the pen tip. These dynamics may be used and optimized for many functions including ultra-high-resolution lithography, Tip-enhanced Raman Spectroscopy (TERS), photothermal pen actuation or plasmon-driven photocatalysis.
A custom design of a digital light processing unit (DLP) that can allow (via a combination of hardware and software elements) high illumination uniformity (power is ±5% about the average over >95% of the illumination area) [footnote: These images were achieved with a different exposure time; the corrected image corresponds to a greater exposure time. Overall uniformity can be achieved at the expense of energy loss.], easily swappable objective lenses, and dual-LED illumination. The DLP system can feature a DMD chipset (e.g., 0.95″, 1920×1080, or an alternative), with a custom projection lens assembly that can achieve high contrast and highly uniform image quality over the full projection area. Disclosed systems also can utilize custom optics (including light homogenization rod and RTIR prism) to enhance the brightness and uniformity of projection. Additionally, each DLP can be calibrated with a unique correction profile that ensures maximum illumination uniformity for each DLP. The correction profile calibration can be achieved by, first, capturing the native light intensity profile from the DMD at the DLP focus with a beam profiler, thereby determining the power delivered at the focus for each individual DMD mirror. Then, the intensity profile can be normalized programmatically by adjusting each individual mirror's duty cycle (i.e., for a given time period, each DMD mirror is programmed to spend a certain percentage of that time in its ‘ON’ state, sending light down the optical path toward the sample, vs. its ‘OFF’ state, where light is rejected from propagating down the optical path toward the sample). The process can be achieved by setting the DMD pixel with the lowest native intensity (PX1) with a duty cycle of 100% (i.e., this pixel is set to be in its ‘ON’ state 100% of the time). All other pixels can be ‘tuned’ to produce the same intensity as PX1 by decreasing their duty cycle in proportion to their native power vs. the power of PX1 (Schematic 2). A pixel size of 10.00 μm, 5.00 mm, 1.25 mm or other size can be achieved by selecting objective lenses of varying magnification. The DLP offers multiwavelength illumination achieved through a dual-LED illumination design (e.g., 365 nm, 385 nm, 405 nm, 460 nm, 532 nm), a CCD or CMOS camera for real-time imaging of the sample or to allow for in-registry alignment to existing structures for a variety of patterning applications.

Grayscale patterning can be applied to enable precise, arbitrary printing of image profiles containing a variety of feature shapes and sizes over the entire surface of the substrate. The same principle used to create the intensity calibration for each DLP can be used in combination with image superposition to print fine features at high-resolution that would otherwise be challenging (if not unachievable) by stitching square pixels together. Grayscale patterning refers to the ability to adjust the duty cycle of each individual pixel of the DMD chipset simultaneously by uploading a grayscale image. A grayscale image works by encoding the duty cycle for each DMD pixel that defines the image directly to the DMD (anywhere between 0%-100%). First, an image of the desired printed features is uploaded to the software. Then, the software breaks down the single image into multiple grayscale images, calibrated to achieve the final printed result. Breaking down the image into a series of grayscale images allows fine control of the exposure dose at the substrate surface on a pixel-by-pixel basis, enabling fine control over feature growth as each grayscale image is projected onto the substrate surface. Finally, the grayscale images are projected in series onto the substrate, building up the print image-by-image to achieve the final desired print.

High-resolution XYZ nano-translation stages to move the sample relative to the array and optics for addressing the interdigitized space between array apertures with micro- or nanoscale precision. Custom software can allow fully arbitrary movements of the OEM components, enabling surface patterning to take place on various sample materials (glass, quartz, fused silica, silcon). An integrated autoalignment technology can combine an in-house software routine with the OEM hardware for autoalignment of the substrate with the array plane through either electrical feedback (contact, capacitive, inductive), multi-point force feedback, and/or optical feedback.

A tip-array stage can enable the parallel alignment of the XY plane of the array to the XY plane of the DLP projection and maintain focus throughout the entire patterning area. This can include an automated routine programmed in the software, combining real-time feedback from the CMOS/CCD camera and camera image analysis using a 2D FFT (Fast Fourier Transform) protocol with high-precision motorized (˜1 μm resolution) XYZ stages. The auto-focusing protocol can be performed at the center of the tip-array, optimizing the DLP Z-axis position for optimum focus (i.e., maximum throughput of the DLP projection through the array tips). First, the DLP can be moved in the XY plane towards center of the tip-array, and the DLP projects a repeating square pattern. Second, the DLP can be moved in the Z-direction towards the tip-array while the CMOS/CCD camera collects images and the software processes those images. Optimum focus of the DLP relative to the tip-array can be achieved when the FFT reports a strong signal indicating that the individual DMD pixels are visible in the image, indicating that the image of the DLP projection is in the same XY plane as the tip-array. Third, the DLP can be locked into the Z-position for optimum focus, and the DLP projects a “BPL printing image”. The “BPL printing image” is illustratively defined as a repeating pattern specifically designed to take into account the array tips'pitch and entrance aperture size, such that all light projected from the DLP will pass through the tip-array when the DLP and array are (perfectly) aligned in the XY plane. In practice, this means that the CMOS/CCD camera will report a blank image when the DLP and array are aligned in the XY plane. Fourth, the tip-array can be iteratively moved in the X and Y directions within the pitch of the tip-array while the CMOS/CCD camera continues to collect images, stopping when the camera reports the lowest intensity image, indicating that maximum light is passing through the array. Fifth, the array can be rotated using a high-precision rotation stage (<0.06° resolution) in the XY plane while the camera continues to collect images, stopping when the camera reports the lowest intensity image within ˜±1°. Steps four and five can be repeated until the camera reports all of the light is passing through the tip-array (i.e., a blank image is collected), thereby validating that both the tip-array and DLP XY planes are in agreement over the entire array surface. The routine can include coarse adjustments to the plane of the array during initial steps, after which, implementing fine adjustments until the best orientation is determined. The rotation and XYZ stages can provide true four axis alignment of the array with respect to the projected image to enable high-throughput, high-uniform image illumination over the sample.

The sample holder is illustratively designed to utilize a vacuum chuck for mounting a sample directly or an enclosed sample chamber that allows control over the liquid or gaseous environment for in situ photochemical patterning. The vacuum chuck component is configured to hold a variety of samples materials, typically 2 cm×2 cm, including silicon, quartz, glass or fused silica. The enclosed sample chamber is illustratively embodied as a custom component designed for in situ synthesis (i.e., synthesis of oligonucleotide sequences, peptide sequences, etc.), and multiplexed surface patterning (i.e., patterning multiple different materials adjacent to one another). Additionally, temperature control of the substrate can be achieved via the use of a thermo-electric heating element placed underneath either the sample holder or vacuum chuck. The thermo-electric heating element illustratively operates in a feedback loop with a PID controller, allowing for precise, arbitrary temperature control over the whole substrate surface. Temperature control using this strategy has been achieved previously in industrial settings and has been successfully implemented by TERA-print in the past for facilitating thermoresponsive materials. Alternative examples of this would include in-registry patterning of cyclical photochemistries. Re-alignment capabilities for in-registry printing in which one can re-align a sample to the system within a tolerance dictated by the hardware accuracy (e.g., 0.100 μm) after it has been misaligned, or removed from the system and replaced for in-registry patterning. This can involve a two-step process in which the in-plane alignment (tip-tilt and Z axes) is first achieved using the previously described FFT autofocusing and parallel alignment protocol. Subsequently, the system records the absolute location of the fiducial mark or feature on the sample which defines the origin of the user-accessible coordinate system. The location of this fiducial marker or feature can be specified manually in which the user accesses the camera feed and inputs X, Y and rotation adjustments to the system until an overlay on top of the camera feed (e.g., alignment grid) is aligned with the visual of the sample feature. This can also be done algorithmically wherein an algorithm processes the camera output and defines the location and rotation offset of the feature automatically.

Sample environment control system offers the ability to introduce 10 or more distinct fluids or gases, each of which can be used for patterning in single-step or multi-step print (i.e., multilayer printing where each subsequent layer can be the same, or different material patterned one at a time). Furthermore, the system includes hardware and software functionalities that enable mixing of up to 10 distinct fluids in arbitrary combinations of 3 (e.g., fluids 1, 2, and 3; fluids 1, 2, and 4, or any other possible combination). This can be achieved using a computer-controlled air, peristaltic, or syringe pump driven manifold in coordination with flow feedback controllers and sensors. This manifold is illustratively comprised of pressure, peristaltic and/or syringe pump driven fluidic reservoirs, flow sensors/controllers, and selector valves to select the fluid(s) to inject. The system features microfluidic chip module(s) to process the fluids in a modular fashion before injection into the sample chamber (e.g., mixing, reaction, etc.). This fluidics system can be configured to cycle reagents or access products developed in previous patterning steps. The fluidics system maximizes chemical compatibility by only utilizing extremely chemically resistant materials (e.g., PEEK, Teflon, Glass, etc.) and incorporates small (<1 mm) ID tubing and low dead volume components to minimize overall system dead volume. These features introduce high cycle performance, reliability, versatility and ease of use. This system can also incorporate a gaseous control manifold in which a pressurized or pumped set of gases is selected and controlled through computer operated flow regulators and valves to satisfy a particular pressure and/or flow rate determined by the user and measured by system inline components.

Flow control can include control hardware including but not limited to pressure pumps, peristaltic pumps, syringe pumps, reservoirs, multi-input valves, check valves, laminar flow mixers, regulators, flow rate monitors and chemically inert tubing. The flow control system can be protected from ambient light and can be capable of mixing reaction precursors directly upstream of the desired reaction chamber. The reaction chamber can be positioned directly below the light path in a chemically inert, sealed assembly allowing for synchronization between photoexposure and flow timing. The instrument can be capable of performing wash steps between each cycle to evacuate cross-contaminants between cycles.

Software that allows full control of the stages, DLP, and fluidics, when applicable, to enable fully automated and user-controlled alignment, pattern design and uploading, patterning sequence definition, and orchestrated operation of the modules to complete the patterns. The user interface can include a sequence of three pages corresponding to the stage involved in setting up and executing the print. The sequence follows generally three main pages: (i.e., Define, Align, Print), however additional software functionalities may exist within these.
In the Define page the user can upload a file containing a single image or sequence of images in a standard grayscale format which defines the layer(s) of the print. These layers may be previewed in sequence to provide a clear visual of the image configurations. The user can then specify print parameters programmatically by creating and naming layer definitions which are then assigned by the user to the desired print layers. These layer definitions can include parameters such as gas or fluid(s) selection, flow rate(s), LED wavelength, LED exposure and intensity. Layer definitions or entire print configurations may be exported in a standard file format and re-uploaded for use in any subsequent prints.
In the Align page the user may manually align samples with full control of the DLP and all motorized stages in the system, using the DLP's integrated live camera feed as feedback for relative and absolute positioning. The user may also have access to automated capabilities for auto-focusing, in-plane alignment and in-registry alignment wherein the system's coordinate system may be redefined to align with the sample as described previously.
In the Print page the user may execute the print. While printing, a preview of the current image being patterned as well as any live metrics such as flow rates are displayed. The user may pause the print in which all processes remain idle until the user resumes the print. The user can also stop the print in which the stages will return to a default position and any fluids or pressurized gas in a sample chamber is purged and the system is returned to its initial state.

Application spaces include but are not limited to microarray fabrication (e.g., DNA, peptides, carbohydrates) via photopatterning or in situ photosynthesis, biosensors, nanoarrays, gene synthesis, oligonucleotides, RNAs, XNAs, DNA for data storage, and multi-omics approaches. Compatible materials include but are not limited to light-reactive biomolecules, hydrogels, biomolecules, polymers, and any other suitable photoresponsive materials.

The combination of photolithographic and microfluidic control systems opens up many possibilities for synthesis applications. It can create custom DNA or RNA arrays for gene expression studies and SNP genotyping, as well as RNA-protein interactions, and scaffolds for DNA origami and enzyme pathways. The system can be used for peptide synthesis and producing high-throughput libraries, custom peptides with specific modifications, and peptide arrays. In illustrative embodiments, the instrument can allow photopolymerization for creating functional polymers, gradient materials, and small-molecule libraries for drug discovery and catalyst research. It can also be used for glycan synthesis to explore carbohydrate-protein interactions and design functional groups to proteins for advanced labeling or hybrid molecule development.

The digital projection system in combination with the microfabrication array can enable diffraction-unlimited photoexposure resolution. This irradiation limits light scattering, internally reflected light and stray light, that can allow for a higher dose and faster photochemistry in liquid environments that are otherwise susceptible to scattering. This improvement in light delivery precision can make cyclical chemistries less prone to errors in synthesis compared to wide-field exposure (ie. DMD based or masked photolithography) and can allow for longer chain lengths with a higher fidelity. The combination of the digitization of light through nanoapertures with the nanoprecise movement from the XY stages can enable densely packed nanoarrays with feature resolution below 200 nm. Arbitrary feature spacing can range down to 200 nm. The maskless approach enables arbitrary patterning, spacing and sequence for each patterned biomolecule such as DNA, RNA, photopolymers or other cyclical photoreaction products. The presence of the probes can reduce the reaction chamber volume, which can reduce dead volume of the reagents. Functionalization of the slides with a deprotectable group can ensure that photochemical reactions are immobilized and capable of extension with cyclical chemistries and nanoprecise registration.

Incorporation of a tip-array for light-driven DNA/RNA synthesis can enable the creation of highly dense DNA/RNA arrays. Such arrays can have greater quality than current industrial methods. Advantages of using a tip-array can be due to two factors: 1.) A single tip can allow a highly spatially focused (diffraction-unlimited) amount of light to be introduced to the sample surface without (effectively) any light scattering, diffraction, flare, etc., and 2.) diffraction-unlimited focusing capability can ensure that every tip in the array (>100,000 s of tips, each separated by 25 μm) acts independently, with (effectively) no light originating from any tip interacting with light from any other tip on the sample surface. Briefly, the sample and tip-array can be brought into contact for DNA synthesis (after the successful completion of the alignment protocols described above), and fluidics can be subsequently flown through the sample holder to create the first layer of DNA bases on the entirety of the sample surface. Then, the DLP can project light through the tip-array to ‘de-protect’ those DNA bases. With the DNA bases de-protected, fluidics can be flown through the sample holder to attach the next DNA base, thereby creating the next layer in the DNA oligo. This process can be repeated until the DNA oligo's are completely synthesized, with the DLP and fluidics coordinated to de-protect DNA bases anywhere on the sample surface as needed, thereby enabling arbitrary DNA oligos to be printed on the sample surface. Throughout this process, each DNA oligo grown is associated with a particular tip, without any light from adjacent tips interacting with the DNA oligo as it is grown. This can reduce (or even eliminate) error occurrence in light-driven DNA synthesis, insertion errors, with the tip-array mediated method. Insertion errors can take place when a DNA base at the end of a DNA oligo is inadvertently deprotected and the next DNA base flown through the sample holder links to the next layer of the DNA oligo, thereby ‘inserting’ a DNA base where none was supposed to be added. Insertion errors are fundamentally due to imperfections in the optical system, with image drift, scattering, flare, etc. all contributing to imperfections in the DNA oligo synthesis. Even in the case of very low insertion error (e.g., 0.5%), DNA oligos of length 25-mer printed on the sample surface would be ˜88% correct. Industrial methods for light-driven DNA synthesis have not overcome insertion errors, producing DNA oligos at low efficiency and at high-cost. Additionally, removing/mitigating these errors using conventional optical methods is, not only costly, but often results in compromising the density of DNA/RNA oligos on the sample surface (i.e., to get higher fidelity DNA/RNA oligos, conventional methods will produce less dense DNA'RNA oligo arrays). The application of the tip-array mediated DNA/RNA synthesis method proposed here not only eliminates the cause of insertion errors by focusing the light beyond the diffraction limit, but can do so without (significantly) decreasing the density of the resultant DNA/RNA oligo arrays (tip arrays can be designed with pitches ranging from 10-100 μm).

Using Polymer Pen Lithography (PPL) in tandem with DMD-based photolithography it is possible to deposit oligonucleotide strands directly onto a pre-functionalized surface or a non-functionalized surface, which are then selectively spatially addressed with light from the DMD. For pre-functionalized surfaces, this workflow can leverage the spatial precision from the contact of the PPL tips coated with specific oligonucleotide sequences for local deposition with the individually addressable light from the DMD mirrors to precisely control which areas get their photolabile groups deprotected and allowed to interact with the phosphoramidite reagent being flown into the sample holder. PPL techniques can be used to deposit the surface functionalization chemistry locally on the sample surface, reducing chemical waste and time needed to functionalize an entire sample surface, before using PPL to deposit nucleotide strands or using BPL to light-driven array synthesis Using PPL to deposit pre-synthesized oligonucleotides can offer a significant advantage over traditional DMD-based photolithography for DNA synthesis in terms of time efficiency. With PPL, direct deposit of a full-length oligonucleotide sequence onto the substrate can be conducted in a single step. This can bypass the need for iterative nucleotide-by-nucleotide synthesis required by traditional DMD systems alone. This can dramatically reduce the synthesis time for creating complex arrays. In contrast, DMD-based synthesis by themselves can require multiple cycles of light exposure and chemical addition to build sequences step by step. By combining PPL to deposit entire sequences and DMD for selective light-based modification or activation, both rapid deposition and precise, programmable control for downstream continuation of synthesis can be achieved.

Within the present disclosure, devices, systems, and methods of high resolution photolithography are discussed. For example, maskless photolithography tools can enable the patterning of photoresponsive materials on a variety of surfaces, over large areas, and with high resolution. Referring to FIG. 1, the high resolution photolithography system 12 comprises a light processing system 14 illustratively embodied as a digital light processing unit (DLP) (forming a UV-projector) mounted to a Z-axis motorized stage 16 for light focusing. A mounting stage 18 illustratively defining a sample holder is illustratively oriented below the DLP (which can include either a substrate chuck (e.g., vacuum chuck) or custom fluid exchange cell) mounted to a positioning system 20 illustratively including high-resolution XY platform (stages) 22 for addressing the sample area and the Z-axis motor stage 16. The system illustratively includes a tip/tilt stage integrated into the sample area assembly to allow adjustment of samples for parallelism with projected light. The system illustratively includes a rotation stage to allow adjustment of samples for orthogonality with the light projection and/or for in-registry printing. The system includes a control system 24 configured for overall operation via processor instructions, which may be embodied as integrated or external computer processor and auxiliaries.

In the illustrative embodiment, the system includes the digital light processing unit (DLP) that can provide high illumination uniformity. For example, high illumination uniformity can include power within over 95% of the illumination area is standardized to be within about ±5% of the average. The system illustratively includes selectable objective lenses according to the particular application, and multi-light source (e.g., LEDs, lasers, fiber optics, etc.) illumination. In the illustrative embodiment, the multi-light source is a dual-LED source, but in some embodiments may include any suitable number and/or manner of light source. The DLP illustratively includes a DMD chipset (e.g., 0.95″, 1920×1080 pixels, or equivalent alternative). The DMD chipset illustratively includes a custom projection lens assembly that can achieve high contrast and/or highly uniform image quality over the full projection area. The high resolution photolithography system also utilize custom optics, for example, including light homogenization rod, RTIR prism, to enhance the brightness and/or uniformity of projection, and/or TIR or RTIR prism used to illuminate the DMD and relay the image into the projection optics.

The DLP is calibrated with a correction profile to enable maximum illumination uniformity for each DLP. The calibration with correction profile is illustratively conducted by capturing the native light intensity profile from the DMD at the DLP focus, for example, with a beam profiler. The power delivered can be determined at the focus for each individual DMD mirror. The captured native light intensity profile can be normalized programmatically by adjusting each individual mirror's duty cycle. For example, for a given period, each DMD mirror can be directed to spend a certain percentage of that time in its ‘ON’ state, sending light down the optical path toward the sample, vs. its ‘OFF’ state, where its light is rejected from propagating down the optical path toward the sample.

By setting the DMD mirror (pixel) with the lowest native intensity (PX1) with a duty cycle of 100% (i.e., this pixel is set to be in its ‘ON’ state 100% of the time). All other pixels can be ‘tuned’ to produce the same intensity as PX1 by decreasing their duty cycle in proportion to their native power vs. the power of PX1 as suggested in FIG. 2. A pixel size of 10.00 μm, 5.00 μm, 1.25 μm or any other suitable size can be achieved by selecting objective lenses of varying magnification. The DLP is configured to provide multi-wavelength illumination achieved through a dual-LED illumination design (e.g., 365 nm, 385 nm, 405 nm, 460 nm, 532 nm). In some embodiments, visual monitoring can be achieved, for example, by CCD or CMOS camera, for real-time imaging of the sample and/or to allow for in-registry alignment to existing structures for a variety of patterning applications.

In some embodiments, grayscale patterning can be applied to enable precise, arbitrary printing of image profiles containing a variety of feature shapes and/or sizes over the surface of the substrate. Similar principles used to create the intensity calibration for each DLP can be applied in combination with image superposition to print fine features at high-resolution. Such features may otherwise be unachievable by stitching square pixels together. Grayscale patterning includes the ability to adjust the duty cycle of each individual pixel of the DMD chipset. Such adjustment can be performed simultaneously by uploading a grayscale image.

For example, the grayscale image can encode the duty cycle for each DMD pixel that defines the image directly to the DMD (anywhere between 0%-100%). Initially, an image of the desired printed features can be received, e.g., uploaded. The single grayscale image can be broken down into multiple grayscale images (e.g., multiple bit planes as 1-bit images), calibrated to achieve the final printed result. Breaking down the image into a series of grayscale images (bit planes) can allow fine control of the exposure dose at the substrate surface on a pixel-by-pixel basis, enabling fine control over feature growth as each bit plane is projected onto the substrate surface. Finally, the bit planes are projected in series onto the substrate, building up the print image-by-image to achieve the final desired print.

In the illustrative embodiment, high-resolution XYZ translation stages can adjust the DLP position relative to the sample for focusing projections onto a sample and/or stitching multiple sub-cm² projection areas together to rapidly pattern multi-projection patterns. In the illustrative embodiment, the relative XY movements occurs by movement of the sample stage, while Z movements occur by movement of the DLP itself, although in some embodiments, movement in any of X, Y, Z dimensions can occur in either or both of sample stage or DLP. Customizable calibration can allow fully arbitrary movements of OEM components, to enable surface patterning to take place on various sample types, for example, on standard microscope slides, 4″ silicon wafers, 6″ silicon wafers, and/or on custom sizes of greater or lesser magnitude, limited only by the maximum travel distance of the configured translation stages. Furthermore, an integrated autofocusing technique can be applied with the OEM hardware for seamless ‘stitching’ of multiple projections with high-precision, enabling repeatable high-precision photopatterning.

In the illustrative embodiment, autofocusing can include uploading a periodic pattern of squares to the DMD (e.g., 48 squares×27 squares, with each square being 20 pixels×20 pixels, spaced 20 pixels apart, for the 1920×1080 DMD), and, for example, projecting this pattern onto the center of the sample, roughly within focus, and the camera can capture the image at the surface. A Fast Fourier Transform (FFT) can be performed on the image to decompose the periodic square pattern in spatial co-ordinates into elements of spatial frequency. The FFT thus converts the image from planar ‘x and y’ co-ordinates to ‘1/x and 1/y’ frequency amplitude. When the pattern of squares is in desired/high focus, such that the pattern indicates its highest contrast, the FFT image data illustrates a high amplitude signal at the spatial frequency defined by the period between each square (e.g., 1/40 pixels⁻¹). When outside of desired/high focus, the FFT image data illustrates diminished amplitude and/or shift to lower spatial frequencies.

The FFT image data can be combined in feedback with the Z-axis motorized stage. The focal plane of the DLP can be adjusted into high focus on the sample surface. In some embodiments, auto-focusing can include optimizing the DLP Z-axis position relative to the maximum intensity of the square pattern, coordinating LED exposure of the sample with the camera (i.e., calculating the distance of the sample from the focus by measuring the amount of time it takes for light to propagate from the sample to the camera), and/or maximizing contrast at the edges of the projected squares. In some embodiments, auto-focusing may apply a laser to achieve precise determination of the time for light to reflect from the sample to the camera, through-the-lens secondary image registration (TTL SIR) (where two images of the DMD image overlap on the camera, with optimum focus being achieved when both images perfectly overlap), and applying an infrared (IR) light source to triangulate the position of the substrate surface with the camera. Such techniques can be incorporated to further increase precision auto-focusing should experimental and/or practical needs require. A precision motorized rotation stage (<0.001° resolution) can provide the capability to align a sample feature to the translation axes of the system. This stage may be adjusted manually for rough alignment followed by precision adjustment via user input and/or automated alignment program.

The Tip-tilt stage can enable the parallel alignment of the XY plane of the sample to the XY plane of the DLP and maintain focus throughout the patterning area. Tip-tilt stage alignment can combine real-time feedback from the camera/auto-focusing detailed in the previous section with a precision motorized (<0.001° resolution) Tip-Tilt stage.

In the illustrative embodiment, tip-tilt alignment can conduct auto-focusing at the center of the sample surface, resolving the DLP Z-axis position for optimum focus, and the Z-axis position can be recorded. The sample stage can be moved relative to the DLP in the XY plane towards the perimeter of the sample, and the auto-focusing can be repeated, such that a new DLP Z-axis position is recorded when optimum focus is reached concerning the perimeter. This process can be repeated multiple times along the edge of the sample. For example, a total of five data points can be produced: one data point for the center of the sample and four data points, in quadrature, along the sample's perimeter.

The five data points can be evaluated programmatically to determine the relative orientation of the sample plane with that of the DLP focal plane. The motorized Tip-tilt stage can adjust the sample plane to be in better agreement with the DLP focal plane. This process can be iterated until the auto-focusing protocol produces five equal Z-axis data points, thereby validating that both planes are in agreement over the entire sample surface. Coarse adjustments to the plane of the substrate can be applied during initial steps, after which, fine adjustments can be implemented until the preferred orientation is achieved. The Tip-Tilt stage in coordination with the rotation and XYZ stages, can provide six-axis alignment of the sample with respect to the projected image to enable in-registry printing where a user or automated program may fully align a sample feature to the projected image.

In another example, tip-tilt alignment can conduct auto-focusing on the perimeter of the sample surface, resolving the DLP Z-axis position for optimum focus, and the Z-axis position can be recorded. The sample stage can be moved relative to the DLP in the XY plane around the perimeter of the sample, and the auto-focusing can be repeated, such that a new DLP Z-axis position is recorded when optimum focus is reached concerning the perimeter. This process can be repeated multiple times along the edge of the sample. For example, a total of three data points can be produced along the sample's perimeter that define a rectangle on the sample surface.

The three data points can be evaluated programmatically to precisely determine the relative orientation of the sample plane with that of the DLP focal plane. The evaluation produces two new XYZ positions, XYZ₁ and XYZ₂, on the substrate and they can be reached with the XYZ translation stages. The motorized Tip-tilt stage and XYZ translation stages co-ordinate using XYZ₁ and XYZ₂ to adjust the sample plane to be in better agreement with the DLP focal plane. The motorized Tip-tilt stage finely adjusts the sample to be in-plane with the DLP, first, at XYZ₁ and, second, at XYZ₂. This can produce three equal Z-axis data points, thereby validating that both planes are in agreement over the entire sample surface. The Tip-Tilt stage in coordination with the rotation and XYZ stages, can provide six-axis alignment of the sample with respect to the projected image to enable in-registry printing where a user or automated program may fully align a sample feature to the projected image.

In the illustrative embodiment, the sample holder is configured to utilize a vacuum chuck for selectively mounting a sample directly or an enclosed sample chamber that allows control over the fluid (liquid and/or gaseous) environment for in situ photochemical patterning. The vacuum chuck component is configured to hold a variety of sample types, for example, including 4/5-inch Silicon wafers, microscope slides, and/or custom sample sizes. The enclosed sample chamber is configured as a custom component designed for in situ synthesis (i.e., synthesis of oligonucleotide sequences, peptide sequences, etc.), and/or multiplexed surface patterning (i.e., patterning multiple different materials adjacent to one another and/or simultaneously).

Additionally, temperature control of the substrate can be achieved via the use of a thermo-electric heating element placed underneath the selected sample holder or substrate chuck. The thermo-electric heating element can operate in a feedback loop with a controller (e.g., PID), allowing for precise temperature control over the substrate surface.

Within the present disclosure, the system illustratively includes re-alignment capabilities for in-registry printing in which a sample can be re-aligned to the system within a tolerance dictated by the hardware accuracy (e.g., 0.100 μm) after misalignments, such as in being removed and replaced from the system for in-registry patterning. In the illustrative embodiment, the in-plane alignment (tip-tilt and Z axes) can be achieved using the previously-described FFT autofocusing and/or parallel alignment techniques. The system can record the absolute location of the fiducial mark or feature on the sample which defines the origin of the user-accessible coordinate system. In some embodiments, the location of this fiducial marker or feature can be specified manually in which the user accesses the camera feed and inputs X, Y and/or rotation adjustments to the system until an overlay on top of the camera feed (e.g., alignment grid) is aligned with the visual of the sample feature. In some embodiments, this mark alignment may also be done partly or wholly algorithmically, wherein an algorithm processes the camera output, defines the location, and/or defines the rotation offset of the feature automatically.

A sample environment control system can provide the ability to introduce multiple (e.g., 1 or more; including e.g., 1, 2, 10, 100, or any other suitable number of fluids) distinct fluids to the sample. Each fluid may be used for patterning in single-step or multi-step print (i.e., multilayer printing where each subsequent layer can be the same, or different material patterned one at a time). Furthermore, the system can include fluidics functionalities, which may include microfluidics, to enable mixing of multiple (e.g., 10 or more) distinct fluids in customizable combinations (e.g., fluids 1, 2, and 3; fluids 1, 2, and 4, or any other suitable combination).

The sample environment control system can provide the ability to introduce one or more distinct fluids into a sealed chamber, for example, in precise microliter volumes. The one or more fluids can be photopatterned using the DLP system (e.g., UV-exposure) in single-step or multi-step printing (i.e., multilayer printing where each subsequent layer can be the same, or different material patterned one at a time). The system can enable mixing of one or more distinct fluids in arbitrary combinations (e.g., fluids 1 and 2; fluids 1, 2, and 3, or any other possible combination) and arbitrary proportions (e.g., fluids 1 and 2 mixed in a 1:3 ratio, or fluids 1, 2, and 3 mixed in a 1:2:3 ratio, or another possible combination). This mixing can be achieved using a computer-controlled manifold in coordination with flow feedback controllers and/or sensors to enable the arbitrary fluidic control disclosed above.

The sample environment control system can provide the ability to pattern onto arbitrary sized substrates used in the sealed fluidics chamber. Standard microscope glass slides, 1″×1″ glass slides, 2″×2″ glass slides, etc. can be fit into the sealed fluidics chamber for printing while exposed to micro-or milli-liter amounts of single or mixed fluids. Substrates of arbitrary composition (e.g., silicon) aside from glass can also be used for fluidics photolithography.

The manifold can be comprised of pressure, peristaltic, and/or syringe pump driven fluidic reservoirs, flow sensors/controllers, and/or selector valves. Control operation can impart coordination to select the fluid(s) to inject. The system can include one or more fluidic chip modules (e.g., micromixer(s) to process the fluids in a modular fashion before injection into the sample chamber (e.g., mixing, reaction, etc.). This fluidics system can be configured to cycle reagents or access products developed in previous patterning steps. Fluidics cycling can be arranged such that unreacted fluid from the sample chamber can be directed to another fluidic chamber, and/or another system for use. This redirection can effectively allow for multiple fluidic chambers or systems to be ‘daisy chained’ together to reduce fluid waste, and/or increasing printing efficiency and/or throughput. The system can include a gaseous control manifold in which a pressurized or pumped set of gases can be selected and/or controlled through computer operated flow regulators and/or valves to satisfy a particular pressure and/or flow rate determined by the user and measured by system inline components. Control operations can permit gases to be introduced and mixed, similarly as disclosed above, via computer-operated flow regulators and/or valves.

For example, the high resolution photolithography system illustratively includes a fluidics system including a computer-controlled air, peristaltic, and/or syringe pump driven manifold in coordination with flow feedback controllers and/or sensors can provide precision control of fluid delivery. The manifold is illustratively comprised of pressure, peristaltic, and/or syringe pump driven fluidic reservoirs, flow sensors/controllers, and/or selector valves to select the fluid(s) to inject. The fluidics system illustratively includes microfluidic chip module(s) to process the fluids in a modular fashion before injection into the sample chamber (e.g., mixing, reaction, etc.). The fluidics system can be configured to cycle reagents or access products developed in previous patterning steps. The fluidics system can enhance chemical compatibility by applying only highly chemically-resistant materials (e.g., PEEK, Teflon, Glass, etc.) and can incorporate small (<1 mm) ID tubing and/or low dead volume components to reduce overall system dead volume. These features can introduce high cycle performance, reliability, versatility, and/or ease of use. The fluidics system can incorporate a gaseous control manifold in which a pressurized or pumped set of gases is selected and controlled through computer-operated flow regulators and/or valves to satisfy a particular pressure and/or flow rate determined by the user and measured by system inline components.

Within the present disclosure, control operations may be included for governing of the stages, DLP, and fluidics, when applicable, to enable fully-automated and wholly or partly user-controlled alignment, pattern design and/or uploading, patterning sequence definition, and/or orchestrated operation of the modules to complete the patterns. A user interface is illustratively composed of a sequence of pages corresponding to the stage involved in setting-up and executing the print. For example, the sequence may follow generally three main pages: (i.e., Define, Align, Print), however additional functionalities may exist within these.

In the Define page, the user can upload a file containing a single image or sequence of images in a standard grayscale format which defines the layer(s) of the print. These layers may be previewed in sequence to provide a clear visual of the image configurations. The user can specifies print parameters programmatically by creating and/or naming layer definitions which are then assigned by the user to the desired print layers. These layer definitions can include parameters such as gas or fluid(s) selection, flow rate(s), LED wavelength, LED exposure, intensity, and/or additional post-processing parameters (e.g. definitions for fluid washing steps, incubation, etc.) for each layer. Layer definitions or entire print configurations may be exported in a standard file format and re-uploaded for use in any subsequent prints. The user interface can incorporate custom scripts which upon upload, can define a print sequence. A user can download a GUI-defined sequence in a script format to save, modify, and/or re-upload for future use. A visual image of the steps and/or associated parameters which define the print sequence can be presented for user validation.

In the Align page, the user can manually align samples with full control of the DLP and all motorized stages in the system, using the DLP's integrated live camera feed as feedback for relative and/or absolute positioning. The user also has access to automated capabilities for auto-focusing, in-plane alignment, and/or in-registry alignment to which the system's coordinate system may be redefined. The interface can integrate with custom user-defined scripts to access raw camera output and/or relevant system metrics, as well as positioning metrics and/or commands to facilitate automated alignment for a specific use case (e.g., sample scanning, sample inspection, alignment to user-defined fiducial markings, etc.). System procedures such as autofocusing, in-plane alignment, and/or in-registry alignment processes may be called and executed as sub-routines.

In the Print page, the user can execute the print. The user can be presented with a visual image of the steps and/or associated parameters involved in the print sequence. While printing, parameters involved in the print sequence and/or a preview of the current image being patterned as well as any live metrics such as flow rates can be displayed. The user may pause the print in which all processes remain idle until the user resumes the print. The user can stop the print, which, in some embodiments, will cause the stages to return to a default position, any fluids or pressurized gas in a sample chamber to be purged, and/or the system can be returned to its initial state.

Application spaces include but are not limited to microfabricating microfluidics devices, other fluidics devices, sensors, and/or wearable electronic devices, microelectronics, microlenses, metamaterials, microrobotics, microarray fabrication (e.g., DNA, peptides, carbohydrates) via photopatterning and/or in situ photosynthesis, and/or tissue engineering. Compatible materials include but are not limited to commercial photoresists, hydrogels, biomolecules, polymers, and/or any other suitable photoresponsive materials.

Referring to FIG. 4, the fluidics system illustratively includes capacity for up to 10 fluid reservoirs 28 (some reservoir openings illustratively available with associated tubing). Each reservoir 28 can be maintained at desired pressure via a pressure regulator 30, illustratively from the same priming pressure of 2 bar from the same pressure source. A waste reservoir 32 can be available for waste materials/fluids. Fluid valves 34, illustratively three, can provide flow of up to three fluids. A pressure manifold 36 can enable independent pressurization of each reservoir 28 from the pressure source. A mixer 38 can receive two or more fluids from the valves 34 and mix the fluids together upstream of dispatch to the sealed sample chamber 38 of the mounting stage.

Referring to FIG. 5, the high resolution photolithography system is shown with integrated fluidics including an objective lens for the Digital Light Projection (DLP) system 14, which focuses the DMD projection onto the substrate; the mounting stage 18 for the substrate, embodied here with the fluidics environment sample holder 38 (fluidic inlet and outlet lines are shown); the positioning system 20 (X- and Y-Axis) illustratively supporting the mounting stage 18, which moves the DLP projection across the substrate printing surface; and the Tip/Tilt system 21 of the positioning system 20, which adjusts the angular offset between the DLP and the mounting stage 18 (and thus, the substrate printing surface).

Devices, systems, and/or methods within the present disclosure may implement control systems for their disclosed operations. Such control systems may include one or more processors embodied, for example, as microprocessors, memory for storing instructions for execution by the processors, and communications circuitry for conducting various operations according to the processors. Examples of suitable processors may include one or more microprocessors, integrated circuits, system-on-a-chips (SoC), among others. Examples of suitable memory, may include one or more primary storage and/or non-primary storage (e.g., secondary, tertiary, etc. storage); permanent, semi-permanent, and/or temporary storage; and/or memory storage devices including but not limited to hard drives (e.g., magnetic, solid state), optical discs (e.g., CD-ROM, DVD-ROM), RAM (e.g., DRAM, SRAM, DRDRAM), ROM (e.g., PROM, EPROM, EEPROM, Flash EEPROM), volatile, and/or non-volatile memory; among others. Communication circuitry may include components for facilitating processor operations, for example, suitable components may include transmitters, receivers, modulators, demodulators, filters, modems, analog/digital (AD or DA) converters, diodes, switches, operational amplifiers, and/or integrated circuits. AI and/or machine learning implementations may include instructions stored on the memory for execution by the processors for disclosed operations. AI and/or machine learning implementations may be embodied as one or more of neural networks, decision tree learning, regression analysis, Gaussian processes, Bayesian optimization and its associated acquisition functions, including any suitable manner of model, for example but without limitation, supervised, quasi-supervised, and/or unsupervised learning models, such as linear regression, logistic regression, decision tree, SVM, Naive Bayes, kNN, k-means, dimensionality reduction algorithms, gradient boosting algorithms (e.g., GBM, LightGBM, CatBoost) style models, GANs, and transformer models.

### CLAUSES

Clause 1: a high-resolution photolithography system comprising: a mounting stage configured to presenting a target sample in position to receive high-resolution, patterned illumination for light-driven photochemistry, a light-processing system configured to provide high-resolution patterned illumination to the target sample, a positioning system configured for adjusting relative positioning between the light-processing system and the mounting stage, and a reagent system configured for application of one or more reagent materials within a patterning environment of the target sample on the mounting stage to facilitate photochemistry directed to the target sample.

Clause 2: The high-resolution photolithography system of clause 1, including a control system for governing control of the reagent system for application of one or more reagent materials within the patterning environment of the target sample.

Clause 3: The high-resolution photolithography system of any preceding clause: wherein the control system is configured for governing control of at least one of the positioning system and the light-processing system for coordinated control to facilitate high-resolution, patterned photochemistry.

Clause 4: The high-resolution photolithography system of any preceding clause: wherein the control system is configured for governing control of one or more of the positioning system, the light-processing system, and the reagent system for organic material synthesis.

Clause 5: The high-resolution photolithography system of any preceding clause: wherein organic material includes one or more oligomer.

Clause 6: The high-resolution photolithography system of any preceding clause: wherein the organic material includes one or more organic polymer.

Clause 7: The high-resolution photolithography system of any preceding clause: wherein the organic material may include one or more nucleic acid.

Clause 8: The high-resolution photolithography system of any preceding clause: wherein the organic material includes one or more peptide.

Clause 9: The high-resolution photolithography system of any preceding clause: wherein the light-processing system is configured to integrate a beam pen lithography tip array to address the target sample.

Clause 10: The high-resolution photolithography system of any preceding clause: wherein the beam pen lithography tip array includes at least one tip coated with a layer, the layer defining one or more small apertures for passing light.

Clause 11: The high-resolution photolithography system of any preceding clause: wherein the layer may be formed as a thin metallic layer.

Clause 12: The high-resolution photolithography system of any preceding clause: wherein the one or more small apertures for passing light is formed by physical and/or chemical application.

Clause 13: The high-resolution photolithography system of any preceding clause: wherein the one or more small apertures is defined near an apex of the at least one tip.

Clause 14: The high-resolution photolithography system of any preceding clause: wherein the one or more apertures is defined such that light passed therethrough for effecting photochemistry on the target sample is configured for generating nanoscale features with dimensions below the diffraction limit of the light source.

Clause 15: The high-resolution photolithography system of any preceding clause: wherein the reagent system is configured to provide liquid phase reagent material.

Clause 16: The high-resolution photolithography system of any preceding clause: wherein the reagent system is configured to provide gaseous phase reagent material.

Clause 17: The high-resolution photolithography system of any preceding clause: wherein the reagent system is configured to provide reagent material in coordination with translation by the positioning system and/or spatially-patterned projected light by the light-processing system for light-directed patterning on the target sample.

Clause 18: The high-resolution photolithography system of any preceding clause: wherein translation by the positioning system includes XY translation.

Clause 19: The high-resolution photolithography system of any preceding clause: wherein translation by the positioning system includes XYZ translation.

Clause 20: The high-resolution photolithography system of any preceding clause: wherein spatially patterned projected light includes spatially patterned projected light for light-directed 3D patterning.

Clause 21: The high-resolution photolithography system of any preceding clause: wherein spatially patterned projected light includes spatially patterned projected light for light-directed 2D patterning.

Clause 22: The high-resolution photolithography system of any preceding clause: wherein spatially patterned projected light includes spatially patterned projected light for light-directed multiplexed patterning.

Clause 23: The high-resolution photolithography system of any preceding clause: wherein spatially patterned projected light includes spatially patterned projected light for light-directed multiplexed 2D patterning and/or multiplexed 3D patterning.

Clause 24: The high-resolution photolithography system of any preceding clause: wherein the reagent system is configured for concurrent application of a first reagent material that is photo-responsive to a first light wavelength and a second reagent material that is photo-responsive to a second light wavelength.

Clause 25: The high-resolution photolithography system of any preceding clause: wherein the first and second light wavelengths are different from each other for in-registry and/or hybrid high-resolution patterning.

Clause 26: The high-resolution photolithography system of any preceding clause: wherein the reagent system is configured for application of reagent materials as building materials for photochemical layer-by-layer synthesis of organic material into spatially encoded, high resolution arrays.

Clause 27: The high-resolution photolithography system of any preceding clause: wherein the organic material includes one or more oligomer.

Clause 28: The high-resolution photolithography system of any preceding clause: wherein the organic material includes one or more organic polymer.

Clause 29: The high-resolution photolithography system of any preceding clause: wherein the organic material includes one or more nucleic acid.

Clause 30: The high-resolution photolithography system of any preceding clause: wherein the organic material includes one or more peptide.

Clause 31: The high-resolution photolithography system of any preceding clause: wherein the light projection system is configured to operate in a grayscale mode to control light dose delivered to each pixel.

Clause 32: The high-resolution photolithography system of any preceding clause: wherein the reagent system includes a flow cell configured to encompass the target sample to apply reagent materials to the target sample during at least one of prior to, during, and after photolithography.

Clause 33: The high-resolution photolithography system of any preceding clause: wherein the light-processing system includes at least one of a spatial light modulator and a digital micromirror.

Clause 34: The high-resolution photolithography system of any preceding clause: wherein the light-processing system includes projection optics.

Clause 35: The high-resolution photolithography system of any preceding clause: wherein the positioning system is configured to provide relative translational and rotational positioning adjustment between the light-processing system and the mounting stage.

Clause 36: The high-resolution photolithography system of any preceding clause: wherein the light-processing system includes a tip array applied to focus light below diffraction limit.

Clause 37: The high-resolution photolithography system of any preceding clause: wherein the tip array is configured for one or more of delivery of chemistries, mechanical stimuli, thermal triggers, and electromagnetic triggers to the target sample and/or a substrate thereof.

Clause 38: The high-resolution photolithography system of any preceding clause: wherein the control system is configured for governing operations of the reagent (fluidics) system to provide fluidics to the substrate to generate a layer of organic material on the substrate.

Clause 39: The high-resolution photolithography system of any preceding clause: wherein the control system is configured for governing operations of the light processing system to project light onto the substrate via the tip array to deprotect designated areas of the layer of organic material.

Clause 40: The high-resolution photolithography system of any preceding clause: wherein the control system is configured for governing operations of the fluidics system to provide fluidics to the substrate to generate another layer of organic material to the deprotected designated areas.

Clause 41: The high-resolution photolithography system of any preceding clause: wherein the layer of organic material includes one or more nucleic acids.

Clause 42: The high-resolution photolithography system of any preceding clause: wherein the other layer of organic material may include one or more nucleic acids such that the layer and the other layer comprise portions of a DNA oligomer or an RNA oligomer.

Clause 43: An (integrated) high-resolution photolithography system comprising: a mounting stage configured to presenting a target sample in position to receive high-resolution, patterned illumination for light-driven photochemistry, a light-processing system configured to provide high-resolution patterned illumination to the target sample, the light-processing system being integrated with a beam pen lithography tip array to address the target sample, and a positioning system configured for adjusting relative positioning between the light-processing system and the mounting stage, and a reagent system configured for application of one or more reagent materials within a patterning environment of the target sample on the mounting stage to facilitate photochemistry directed to the target sample.

Clause 44: The (integrated) high-resolution photolithography system of clause 43: wherein the beam pen lithography tip array includes at least one tip coated with a layer, the layer defining one or more small apertures for passing light.

Clause 45: The (integrated) high-resolution photolithography system of any preceding clause: wherein the layer is formed as a thin metallic layer.

Clause 46: The (integrated) high-resolution photolithography system of any preceding clause: wherein the one or more small apertures for passing light are formed by physical and/or chemical application.

Clause 47: The (integrated) high-resolution photolithography system of any preceding clause: wherein the one or more small apertures are defined near an apex of the at least one tip.

Clause 48: The (integrated) high-resolution photolithography system of any preceding clause: wherein the one or more apertures are defined such that light passed therethrough for effecting photochemistry on the target sample is configured for generating nanoscale features with dimensions below the diffraction limit of the light source.

Clause 49: The (integrated) high-resolution photolithography system of any preceding clause: further comprising a control system for governing control of the reagent system for application of one or more reagent materials within the patterning environment of the target sample.

Clause 50: The (integrated) high-resolution photolithography system of any preceding clause: wherein the control system is configured for governing control of at least one of the positioning system and the light-processing system for coordinated control to facilitate high-resolution, patterned photochemistry.

Clause 51: The (integrated) high-resolution photolithography system of any preceding clause: wherein the control system is configured for governing control of one or more of the positioning system, the light-processing system, and the reagent system for organic material synthesis.

Clause 52: The (integrated) high-resolution photolithography system of any preceding clause: wherein the organic material includes one or more oligomer.

Clause 53: The (integrated) high-resolution photolithography system of any preceding clause: wherein the organic material includes one or more organic polymer.

Clause 54: The (integrated) high-resolution photolithography system of any preceding clause: wherein the organic material includes one or more nucleic acid.

Clause 55: The (integrated) high-resolution photolithography system of any preceding clause: wherein the organic material includes one or more peptide.

Clause 56: The (integrated) high-resolution photolithography system of any preceding clause: wherein the reagent system is configured to provide liquid phase reagent material.

Clause 57: The (integrated) high-resolution photolithography system of any preceding clause: wherein the reagent system is configured to provide gaseous phase reagent material.

Clause 58: The (integrated) high-resolution photolithography system of any preceding clause: wherein the reagent system is configured to provide reagent material in coordination with translation by the positioning system and/or spatially-patterned projected light by the light-processing system for light-directed patterning on the target sample.

Clause 59: The (integrated) high-resolution photolithography system of any preceding clause: wherein translation by the positioning system includes XY translation.

Clause 60: The (integrated) high-resolution photolithography system of any preceding clause: wherein translation by the positioning system inlcudes XYZ translation.

Clause 61: The (integrated) high-resolution photolithography system of any preceding clause: wherein spatially patterned projected light includes spatially patterned projected light for light-directed 3D patterning.

Clause 62: The (integrated) high-resolution photolithography system of any preceding clause: wherein spatially patterned projected light includes spatially patterned projected light for light-directed 2D patterning.

Clause 63: The (integrated) high-resolution photolithography system of any preceding clause: wherein spatially patterned projected light includes spatially patterned projected light for light-directed multiplexed patterning.

Clause 64: The (integrated) high-resolution photolithography system of any preceding clause: wherein spatially patterned projected light includes spatially patterned projected light for light-directed multiplexed 2D patterning and/or multiplexed 3D patterning.

Clause 65: The (integrated) high-resolution photolithography system of any preceding clause: wherein the reagent system is configured for concurrent application of a first reagent material that is photo-responsive to a first light wavelength and a second reagent material that is photo-responsive to a second light wavelength.

Clause 66: The (integrated) high-resolution photolithography system of any preceding clause: wherein the first and second light wavelengths are different from each other for in-registry and/or hybrid high-resolution patterning.

Clause 67: The (integrated) high-resolution photolithography system of any preceding clause: wherein the reagent system is configured for application of reagent materials as building materials for photochemical layer-by-layer synthesis of organic material into spatially encoded, high resolution arrays.

Clause 68: The (integrated) high-resolution photolithography system of any preceding clause: wherein the organic material includes one or more oligomer.

Clause 69: The (integrated) high-resolution photolithography system of any preceding clause: wherein the organic material includes one or more organic polymer.

Clause 70: The (integrated) high-resolution photolithography system of any preceding clause: wherein the organic material includes one or more nucleic acid.

Clause 71: The (integrated) high-resolution photolithography system of any preceding clause: wherein the organic material includes one or more peptide.

Clause 72: The (integrated) high-resolution photolithography system of any preceding clause: wherein the light projection system is configured to operate in a grayscale mode to control light dose delivered to each pixel.

Clause 73: The (integrated) high-resolution photolithography system of any preceding clause: wherein the reagent system includes a flow cell configured to encompass the target sample to apply reagent materials to the target sample during at least one of prior to, during, and after photolithography.

Clause 74: The (integrated) high-resolution photolithography system of any preceding clause: wherein the light-processing system includes at least one of a spatial light modulator and a digital micromirror.

Clause 75: The (integrated) high-resolution photolithography system of any preceding clause: wherein the light-processing system includes projection optics.

Clause 76: The (integrated) high-resolution photolithography system of any preceding clause: wherein the positioning system is configured to provide relative translational and rotational positioning adjustment between the light-processing system and the mounting stage.

Clause 78: The (integrated) high-resolution photolithography system of any preceding clause: wherein the light-processing system includes a tip array applied to focus light below diffraction limit.

Clause 79: The (integrated) high-resolution photolithography system of any preceding clause: wherein the tip array is configured for one or more of delivery of chemistries, mechanical stimuli, thermal triggers, and electromagnetic triggers to the target sample and/or a substrate thereof.

Clause 80: The (integrated) high-resolution photolithography system of any preceding clause: wherein the control system is configured for governing operations of the reagent (fluidics) system to provide fluidics to the substrate to generate a layer of organic material on the substrate.

Clause 81: The (integrated) high-resolution photolithography system of any preceding clause: wherein the control system is configured for governing operations of the light processing system to project light onto the substrate via the tip array to deprotect designated areas of the layer of organic material.

Clause 82: The (integrated) high-resolution photolithography system of any preceding clause: wherein the control system is configured for governing operations of the fluidics system to provide fluidics to the substrate to generate another layer of organic material to the deprotected designated areas.

Clause 83: The (integrated) high-resolution photolithography system of any preceding clause: wherein the layer of organic material includes one or more nucleic acids.

Clause 84: The (integrated) high-resolution photolithography system of any preceding clause: wherein the other layer of organic material includes one or more nucleic acids such that the layer and the other layer comprise portions of a DNA oligomer or an RNA oligomer.

Accordingly, the various embodiments of the invention, as disclosed above, are intended to be illustrative, not limiting. Various changes may be made without departing from the spirit and scope of the invention. As a result, it will be apparent for those skilled in the art that the illustrative embodiments described are only examples and that various modifications can be made within the scope of the invention as defined in the appended claims.

What is claimed is:

1. A high-resolution photolithography system, comprising:
a mounting stage configured to presenting a target sample in position to receive high-resolution, patterned illumination for light-driven photochemistry;
a light-processing system configured to provide high-resolution patterned illumination to the target sample;
a positioning system configured for adjusting relative positioning between the light-processing system and the mounting stage; and
a reagent system configured for application of one or more reagent materials within a patterning environment of the target sample on the mounting stage to facilitate photochemistry directed to the target sample.

2. The high resolution photolithography system of claim 1, further comprising a control system for governing control of the reagent system for application of one or more reagent materials within the patterning environment of the target sample.

3. The high resolution photolithography system of claim 2, wherein the control system is further configured for governing control of at least one of the positioning system and the light-processing system for coordinated control to facilitate high-resolution, patterned photochemistry.

4. The high resolution photolithography system of claim 3, wherein the control system is configured for governing control of one or more of the positioning system, the light-processing system, and the reagent system for organic material synthesis.

5. The high resolution photolithography system of claim 1, wherein the light-processing system is configured to integrate a beam pen lithography tip array to address the target sample.

6. The high resolution photolithography system of claim 1, wherein the reagent system is configured to provide liquid phase reagent in coordination with translation by the positioning system and spatially-patterned projected light by the light-processing system for light-directed patterning on the target sample.

7. The high resolution photolithography system of claim 6, wherein translation by the positioning system includes XYZ translation.

8. The high resolution photolithography system of claim 6, wherein spatially patterned projected light includes spatially patterned projected light for light-directed 3D patterning.

9. The high resolution photolithography system of claim 6, wherein spatially patterned projected light includes spatially patterned projected light for light-directed multiplexed patterning.

10. The high resolution photolithography system of claim 1, wherein the reagent system is configured for concurrent application of a first reagent material that is photo-responsive to a first light wavelength and a second reagent material that is photo-responsive to a second light wavelength, wherein the first and second light wavelengths are different from each other for in-registry and/or hybrid high-resolution patterning.

11. The high resolution photolithography system of claim 1, wherein the reagent system is configured for application of reagent materials as building materials for photochemical layer-by-layer synthesis of organic material into spatially encoded, high resolution arrays.

12. The high resolution photolithography system of claim 1, wherein the light projection system is configured to operate in a grayscale mode controlling light dose delivered to each pixel.

13. The high resolution photolithography system of claim 1, wherein the reagent system includes a flow cell configured to encompass the target sample to apply reagent materials to the target sample during at least one of prior to, during, and after photolithography.

14. The high resolution photolithography system of claim 1, wherein the light-processing system includes at least one of a spatial light modulator and a digital micromirror.

15. The high resolution photolithography system of claim 1, wherein the light-processing system includes projection optics.

16. The high resolution photolithography system of claim 1, wherein the positioning system is configured to provide relative translational and rotational positioning adjustment between the light-processing system and the mounting stage.
